(19) United States
(12) Patent Application Publication
(10) Pub. No.: US 2012/0182709 A1
(43) Pub. Date: Jul. 19, 2012

(54) SUPPORT ARM AND IMAGE DISPLAY DEVICE

(76) Inventors: Akimasa Asai, Tokyo (JP); Kazuhiko Hayakawa, Tokyo (JP)

(21) Appl. No.: 13/353,100

(22) Filed: Jan. 18, 2012

(30) Foreign Application Priority Data
Jan. 19, 2011 (JP) 2011-009155

(51) Int. Cl. H05K 7/02; H05K 7/14

(52) U.S. Cl. 361/810; 248/224.8

(57) ABSTRACT

A support arm configured to support an image display unit on a device main body of an image display device is provided. The support arm includes a first arm portion including a first end portion coupled to the device main body, a second arm portion including a first end portion coupled to a second end portion of the first arm portion, and vertically rotatable with respect to the first arm portion, and a third arm portion including a first end portion coupled to a second end portion of the second arm portion, and including a second end portion coupled to the image display unit, wherein the first arm portion includes a rod-like engagement member including a hooked portion in a tip portion thereof, and the first end portion of the third arm portion includes an engagement hole configured to engage the hooked portion.

### CROSS REFERENCE TO RELATED APPLICATIONS

This application claims the benefit of Japanese Patent Application No. 2011-009155 filed Jan. 19, 2011, which is hereby incorporated by reference in its entirety.

### BACKGROUND OF THE INVENTION

The present invention relates to a support arm which supports an image display unit on a device main body of an image display device and to the image display device.

As an example of an image display device, an ultrasonic image display device displays an ultrasonic image produced based on an ultrasonic echo signal transmitted to a subject under examination. The ultrasonic image display device has wheels provided in the lower part of the device main body, and is easily movable.

In recent years, an image display unit has been undergoing a transition from a CRT (Cathode Ray Tube) to a thin display such as an LCD (Liquid Crystal Display), and has been becoming increasingly lighter in weight. Due to the lighter weight, it has become possible to provide the foregoing image display unit in the foregoing device main body via a support arm including a plurality of arms, and change the position of the foregoing image display unit using the support arm. For example, in Japanese Unexamined Patent Publication No. 2008-142331, the foregoing image display unit is provided in the device main body via a support arm including a first arm portion, a second arm portion, and a third arm portion.

In Japanese Unexamined Patent Publication No. 2008-142331, the foregoing first arm portion is horizontally rotatable with respect to the device main body, the foregoing second arm is horizontally rotatable with respect to the foregoing first arm portion, and the foregoing third arm portion is horizontally rotatable with respect to the foregoing second arm portion. Such a structure allows the foregoing image display unit to be moved to a position where an operator or the like has a good view of an image.

However, since the movement of the foregoing image display unit is allowed, when an ultrasonic image display device is moved, the foregoing image display unit may move due to vibration or shaking to possibly hit a wall or the like. Accordingly, in Japanese Unexamined Patent Publication No. 2008-142331, a hook provided in the foregoing first arm portion is brought into engagement with an engagement portion provided in the foregoing second arm to lock the rotation of the foregoing second arm portion with respect to the foregoing first arm portion. Also, the engagement of the foregoing hook with the foregoing engagement portion causes a rod provided in the engagement portion to project into a rod hole provided in the foregoing third arm portion to lock the rotation of the foregoing first arm portion with respect to the foregoing second arm portion.

However, in the structure of the support arm disclosed in Japanese Unexamined Patent Publication No. 2008-142331, each of the foregoing first, second, and third arm portions rotates only in a horizontal direction. Therefore, the lock structure of each of the foregoing arm portions is also configured assuming the horizontal rotation, and is not configured to be capable of locking the vertically rotating arm portion. Accordingly, at least some known support arms do not enable a vertically rotating arm portion to be locked.

### SUMMARY OF THE INVENTION

In one aspect a support arm is provided. The support arm includes a first arm portion having one end portion provided on a device main body, a second arm portion having one end portion provided on the other end portion of the first arm portion, and vertically rotatable with respect to the first arm portion, and a third arm portion having one end portion provided on the other end portion of the foregoing second arm portion, and having the other end portion provided with the foregoing image display unit, wherein the foregoing first arm portion is provided with a rod-like engagement member having a hooked portion in a tip portion thereof, and the one end portion of the foregoing third arm portion is provided with an engagement hole with which the foregoing hooked portion is engaged.

In another aspect, an image display device is provided. The image display device includes the support arm, wherein the image display unit is supported on the device main body by the support arm, the device main body includes a casing unit, an arm attached to an attachment portion provided above the foregoing casing unit to be vertically rotatable and extend in a device front-rear direction above the casing unit, and an operation panel provided on a front end side of the arm, and the attachment portion is provided at a position at a predetermined height from an upper surface of the casing unit so as to be rotatable upwardly and downwardly above and below a position where the arm is horizontal.

In the support arm and the image display device described herein, the engagement of the hooked portion of the engagement member provided in the first arm portion with the engagement hole provided in the third arm portion allows the second arm portion that is vertically rotatable and the third arm portion that is provided in the second arm portion and vertically rotatable in association with the second arm portion to be locked with respect to the first arm portion.

By rotating the arm, it is possible to vertically move the operation panel provided on the front end side of the arm. The arm is attached to the attachment portion provided above the casing unit to extend in the device front-rear direction and vertically rotate above the casing unit. This allows the depth (length in the device front-rear direction) of the image display device to be suppressed. In addition, since the arm can upwardly and downwardly rotate above and below a position where it is horizontal, the difference in the position of the operation panel in the device front-rear direction due to the rotation of the arm is reduced. Thus, the depth of the image display device is suppressed to allow space-saving installation.

### BRIEF DESCRIPTION OF THE DRAWINGS

FIG. 1 shows a front view of an exemplary ultrasonic image display device.

FIG. 2 is a side view of the ultrasonic image display device shown in FIG. 1.

FIG. 3 is a plan view of the ultrasonic image display device shown in FIG. 1.

FIG. 4 is a perspective view obtained by viewing the ultrasonic image display device shown in FIG. 1 from the back side thereof

FIG. 5 is an illustrative view of the rotation angle of an arm in the ultrasonic image display device shown in FIG. 1.

FIGS. 6A-6C are illustrative views of the link mechanism of the arm in the ultrasonic image display device shown in FIG. 1.

FIG. 7 is a side view of a display unit support arm.

FIG. 8 is a side view of the display unit support arm in a state where an engagement member is engaged with an engagement hole.

FIG. 9 is a partially enlarged plan view of a first arm portion.

FIG. 10 is a schematic view showing the interior of the first arm portion, which is a view showing a state where the engagement member is at an engagement position.

FIG. 11 is a schematic view showing the interior of the first arm portion, which is a view showing a state where the engagement member is at a storage position.

FIG. 12 is a plan view showing a mounting surface for the first arm portion.

FIG. 13 is a right side view showing the ultrasonic image display device in a state where the arm is at the uppermost position.

FIG. 14 is a right side view showing the ultrasonic image display device in a state where the arm is at the lowermost position.

FIGS. 15 A and 15B are front and plan views, resepectively, illustrating a scene when an operator is squatting to perform scanning.

FIG. 16 is a perspective view showing the ultrasonic image display device in a state where an operation panel is horizontally rotated.

FIG. 17 is a plan view showing the ultrasonic image display device which is installed such that caster attachment members are inserted under a bed.

### DETAILED DESCRIPTION OF THE INVENTION

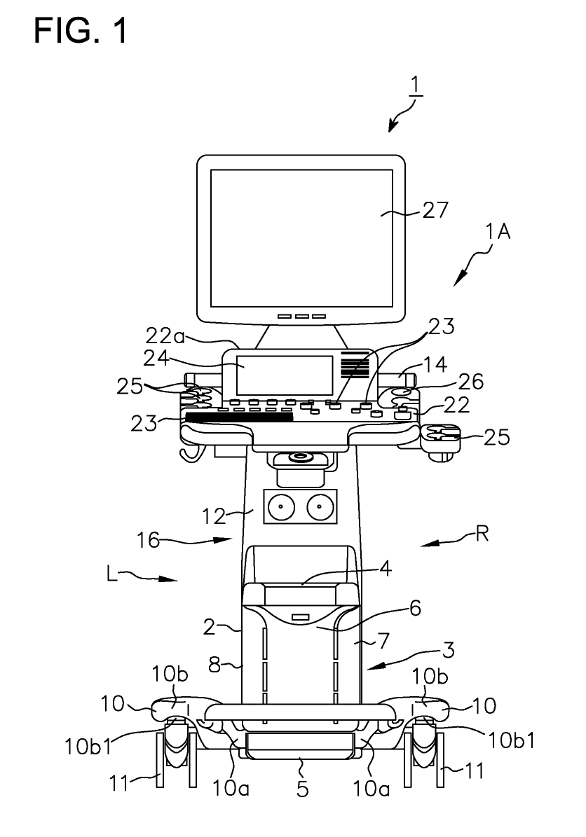

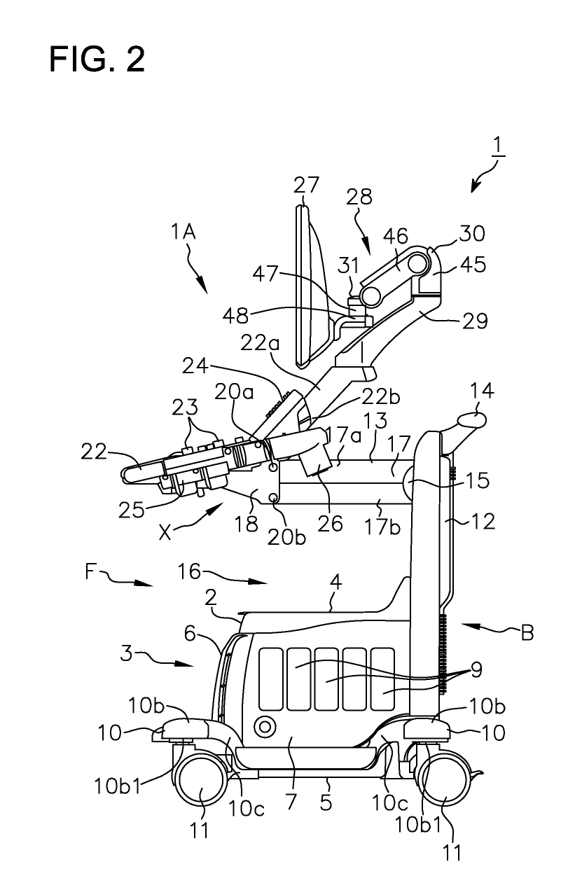

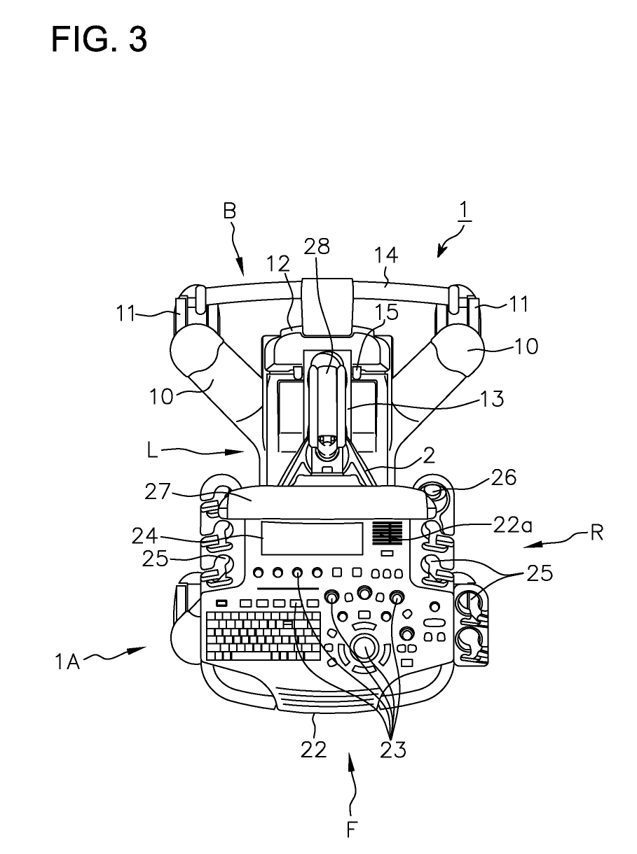

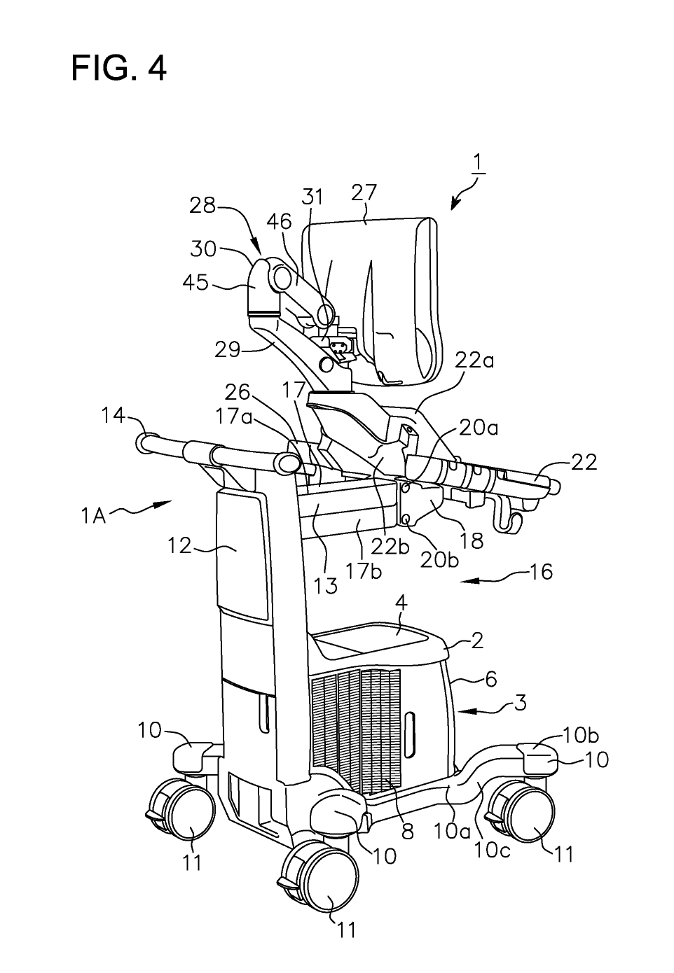

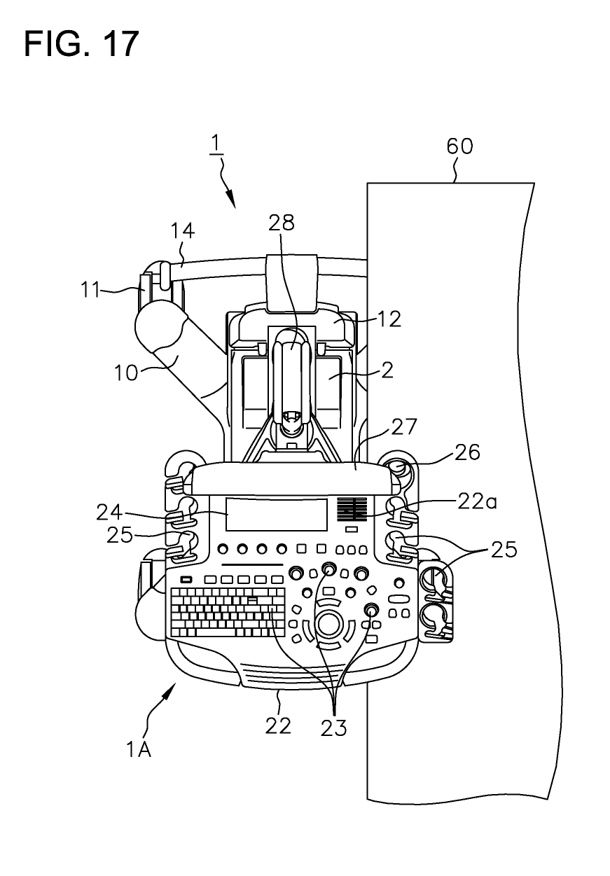

Exemplary embodiments are described herein with reference to FIGS. 1 to 17. An ultrasonic image display device 1 shown in the drawings is a device which displays an ultrasonic image as an image for medical use produced based on an ultrasonic echo signal transmitted to a subject under examination, and is an example of an embodiment of an image display device. A device main body 1A of the ultrasonic image display device 1 includes a casing unit 2 having a generally rectangular parallelepiped shape. The device main body 1A also includes, besides the foregoing casing unit 2, an arm attachment member 12, an arm 13, an operation panel 22, and the like, which will be described later. On the operation panel 22, a display unit 27 is provided via a display unit support arm 28, which will be described later.

In the foregoing casing unit 2 are contained a circuit board including an arithmetic processing unit which performs arithmetic processing of the echo signal obtained by transmitting/receiving an ultrasonic wave from an ultrasonic probe (the depiction thereof is omitted) to produce ultrasonic image data and the like.

Of the four side surfaces 3 (surfaces other than an upper surface 4 and a lower surface 5) of the foregoing casing unit 2, the surface on the side where an operator performs an operation at the operation panel 22 is assumed to be a front surface 6. Accordingly, of the four side surfaces 3 of the foregoing casing unit 2, the right side surface is denoted by a numeral 7 and the left side surface is denoted by a numeral 8.

It is assumed that, in the following description, in the foregoing ultrasonic image display device 1, the front surface 6 side of the foregoing casing unit 2 is referred to as a front surface side F of the foregoing ultrasonic image display device 1, the foregoing right side surface 7 side thereof is referred to as a right side surface side R of the foregoing ultrasonic image display device 1, and the foregoing left side surface 8 side thereof is referred to as a left side surface side L of the foregoing ultrasonic image display device 1. It is also assumed that the side opposing the foregoing front surface side F is referred to as a back surface side B of the foregoing ultrasonic image display device 1.

In the foregoing right side surface 7 of the foregoing casing unit 2, a plurality of connectors 9 (five in the exemplary embodiment) each for connecting the foregoing ultrasonic probe are provided. Thus, since the foregoing connectors 9 are provided in the foregoing right side surface 7, compared with the case where the connectors 9 are provided in the foregoing front surface 6, the width (lateral width) of the foregoing casing unit 2 can be reduced. Note that the foregoing connectors 9 may also be provided in the foregoing left side surface 8.

In the lower part of the foregoing casing unit 2, four caster attachment members 10 are provided so as to protrude laterally from the casing unit 2. In the exemplary embodiment, the two caster attachment members 10 are provided in each of the right side surface 7 and the left side surface 8 of the foregoing casing unit 2. To the foregoing individual caster attachment members 10, casters 11 which support the foregoing ultrasonic image display device 1 at an installation surface are attached in one-to-one correspondence.

Note that of laterally from the foregoing casing unit 2 means toward the periphery of the foregoing ultrasonic image display device 1. Therefore, the protruding direction of each of the foregoing caster attachment members 10 may be any direction within a 360° range around the foregoing ultrasonic image display device 1. In the exemplary embodiment, each of the foregoing caster attachment members 10 protrudes obliquely with respect to the right side surface 7 and the left side surface 8 of the foregoing casing unit 2 toward the foregoing front surface side F and the foregoing back surface side B when viewed in plan view.

Each of the foregoing caster attachment members 10 has an inclined portion 10c which is inclined obliquely upwardly from a proximal end portion 10a toward a tip portion 10b, and the height position of the foregoing tip portion 10b from the installation surface of the foregoing ultrasonic image display device 1 is higher than that of the foregoing proximal end portion 10a. The height position of the foregoing tip portion 10b from the foregoing installation surface is higher than that of the lower surface 5 of the foregoing casing unit 2.

Here, each of the foregoing casters 11 is attached to the lower surface 10b1 of the foregoing tip portion 10b. Accordingly, the height position of the foregoing lower surface 10b1, which is the attachment surface of the foregoing caster 11, from the foregoing installation surface is higher than that of the lower surface 5 of the foregoing casing unit 2. This allows the lower surface 5 of the foregoing casing unit 2 to be brought closer to the foregoing installation surface and therefore allows the height of the foregoing casing unit 2 from the foregoing installation surface to be reduced.

The device main body 1A of the foregoing ultrasonic image display device 1 has the arm attachment member 12 having a flat plate shape on the back surface side B. The arm attachment member 12 is provided integrally with the foregoing casing unit 2, and protrudes upwardly above the upper surface 4 of the casing unit 2. The foregoing arm attachment member 12 has the arm 13 provided on the surface thereof on the casing unit 2 side, while having a rod-like grip member 14 on the opposite surface thereof The operator holds the foregoing grip member 14 and pushes the ultrasonic image display device 1 to thereby allow the ultrasonic image display device 1 to be moved. That is, the ultrasonic image display device 1 has portability.

The foregoing arm 13 is attached to an attachment portion 15 provided in the foregoing arm attachment member 12 to be vertically rotatable. The following is a detailed description thereof The foregoing arm 13 is provided to extend from the foregoing attachment portion 15 toward the foregoing front surface side F. Here, the foregoing front surface side F is the front surface side of the foregoing ultrasonic image display device 1, and the foregoing back surface side B is the back surface side of the foregoing ultrasonic image display device 1. Therefore, it can also be said that the foregoing arm 13 extends in the front-rear direction (device front-rear direction) of the foregoing ultrasonic image display device 1. The length of the foregoing arm 13 is substantially the same as the length of the depth (length in the front-rear direction) of the foregoing casing unit 2.

The foregoing attachment portion 15 is provided above the foregoing casing unit 2. Therefore, the foregoing arm 13 is located above the foregoing casing unit 2. The following is a description of the height position of the foregoing attachment portion 15. The foregoing attachment portion 15 is provided at a position at a predetermined height from the upper surface 4 of the foregoing casing unit 2. The predetermined height is set such that a space portion 16 which allows the foregoing arm 13 to rotate downwardly below a horizontal position X where it is horizontally positioned is formed above the foregoing casing unit 2.

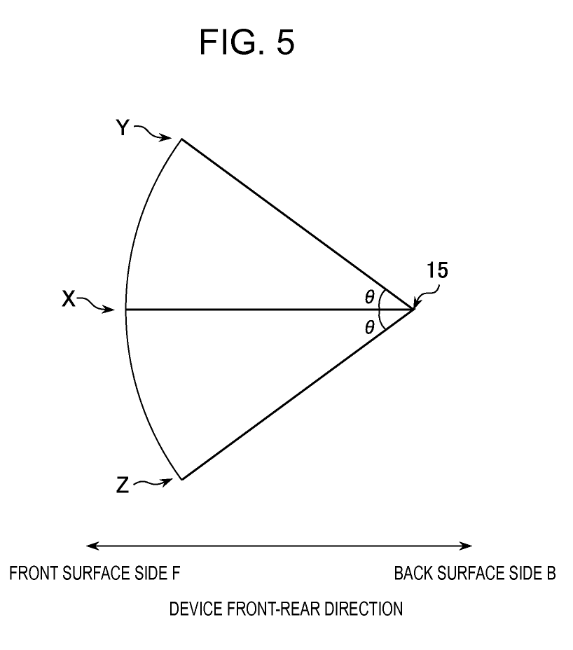

Here, a description will be given of the rotation angle of the foregoing arm 13. The foregoing arm 13 is adapted to rotate upwardly and downwardly each by the same angle θ° from the horizontal position X where it is horizontally positioned, as shown in FIG. 5. The uppermost position reached by the foregoing arm 13 that has rotated θ° upward from the foregoing horizontal position X is assumed to be Y, and the lowermost position reached by the foregoing arm 13 that has rotated θ° downward from the foregoing horizontal position X is assumed to be Z. Thus, the foregoing arm 13 is adapted to rotate upward and downward each by the same angle from the horizontal position X, and therefore the position in the device front-rear direction of the operation panel 22 attached to the front end of the foregoing arm 13 is the same at the foregoing uppermost position Y and at the foregoing lowermost position Z. At the foregoing horizontal position X, the position in the device front-rear direction of the foregoing operation panel 22 is closer to the foregoing front surface side F than at the foregoing uppermost position Y and the foregoing lowermost position Z.

In addition, since the foregoing arm 13 is adapted to rotate upward and downward each by the same angle θ° from the foregoing horizontal position X, compared with the case where the foregoing arm 13 is supposedly adapted to rotate only upward or downward from the foregoing horizontal position X, the difference in the position of the arm 13 in the device front-rear direction between the foregoing horizontal position X and each of the foregoing uppermost position Y and the foregoing lowermost position Z is reduced.

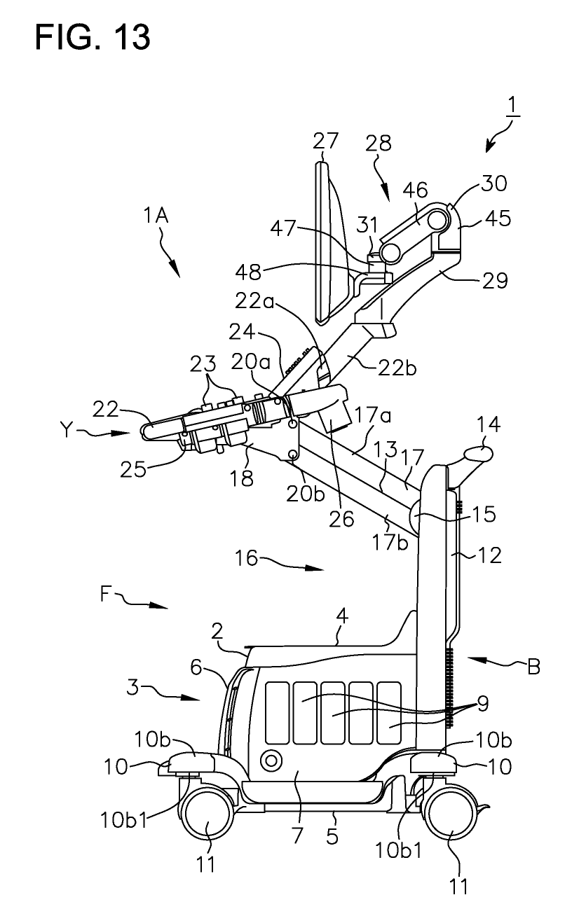

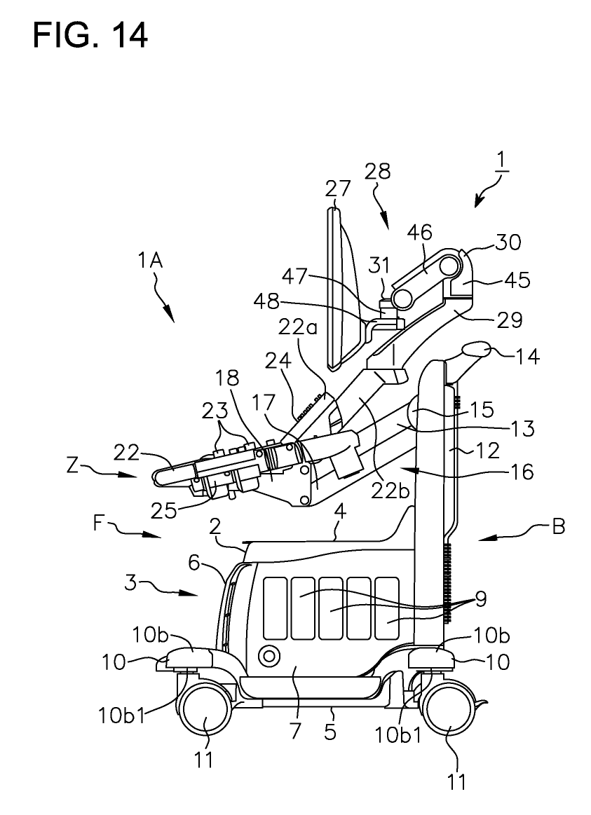

Note that, in FIGS. 1 to 4, a state where the foregoing arm 13 is at the foregoing horizontal position X is shown. In FIG. 13 which will be described later, a state where the foregoing arm 13 is at the foregoing uppermost position Y is shown. In FIG. 14 which will be described later, a state where the foregoing arm 13 is at the foregoing lowermost position Z is shown.

The operation panel 22 is attached to the front end of the foregoing arm 13, as will be described later. In a state where the foregoing arm 13 has rotated to the foregoing uppermost position Y, the operation panel 22 is at a position of 120 to 130 cm from the installation surface in the exemplary embodiment. In a state where the foregoing arm 13 has rotated to the foregoing lowermost position Z the foregoing operation panel 22 is at a position of about 60 cm from the installation surface in the exemplary embodiment. The foregoing horizontal position X is a middle position between the foregoing uppermost position Y and the foregoing lowermost position Z.

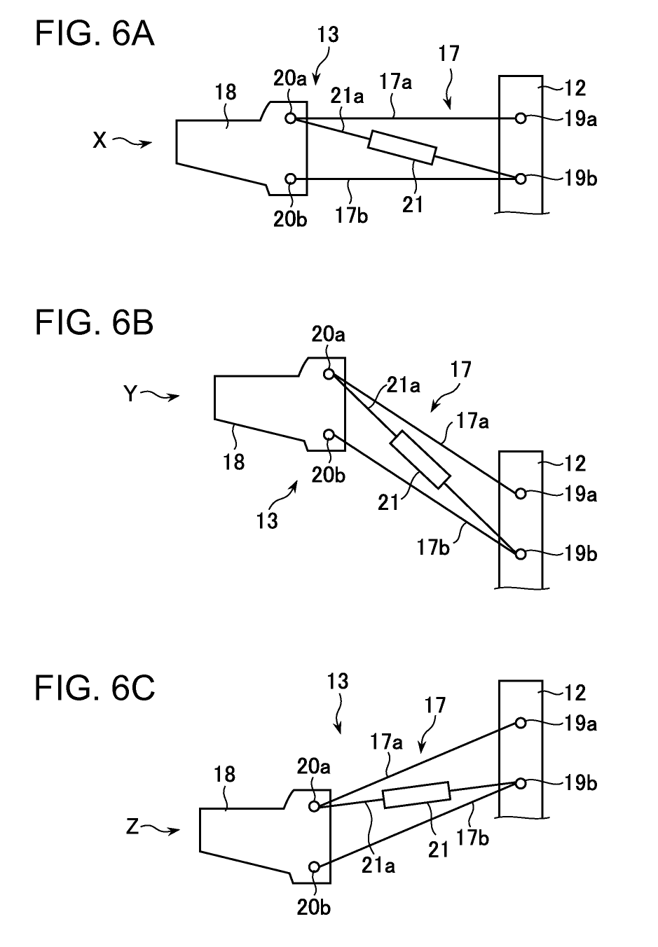

The foregoing arm 13 includes a proximal-end-side first member 17 and a front-end-side second member 18. The foregoing first member 17 includes an upper member 17a and a lower member 17b. The following is a more detailed description thereof FIG. 6A shows the arm 13 in a horizontal position, FIG. 6B shows the arm 13 in an uppermost position, and FIG. 6C shows the arm 13 in a lowermost position. As shown in FIGS. 6A-6C, the foregoing upper member 17a and the foregoing lower member 17b form a parallel link mechanism in which the both end portions thereof are axially supported by axial support portions 19a and 19b of the foregoing arm attachment member 12 and axial support portions 20a and 20b of the foregoing second member 18. The axial support portion 20a of the foregoing upper member 17a on the foregoing second member 18 side and the axial support portion 19b of the foregoing lower member 17b on the foregoing arm attachment member 12 side are connected by a gas spring 21. Note that FIGS. 6A-6C are conceptual views for illustration.

By the foregoing gas spring 21, the position of the foregoing arm 13 is fixed. Specifically, the foregoing gas spring 21 has a lock mechanism (the depiction thereof is omitted) by which the slide of a shaft 21a thereof is locked. The foregoing gas spring 21 is adapted to press the foregoing axial support portion 20a and the foregoing axial support portion 19b with the movement of the foregoing shaft 21a being locked, whereby the position of the foregoing arm 13 is fixed.

By pressing a button (the depiction thereof is omitted) provided on the operation panel 22, the foregoing lock mechanism is unlocked to make the foregoing shaft 21a slidable, thereby allowing the foregoing arm 13 to rotate, as shown in FIGS. 6A-6C. When the button is released, the foregoing shaft 21a is locked, and the position of the foregoing arm 13 is fixed.

The front end of the foregoing second member 18 is provided with the operation panel 22. Accordingly, the foregoing operation panel 22 provided at such a position is located on the front surface side F of the foregoing ultrasonic image display device 1.

The foregoing second member 18 is provided on the lower surface of the foregoing operation panel 22, and the operation panel 22 is provided horizontally rotatable with respect to the foregoing second member 18.

On the foregoing operation panel 22, operation tools 23 such a keyboard, operation buttons, and a track ball are provided. All the operation tools 23 are provided on the upper surface of the foregoing operation panel 22. The foregoing operation panel 22 is provided with a touch-panel-type sub-display 24. The sub-display 24 is adapted to display, for example, buttons for operation and the like.

On the both left and right sides of the foregoing operation panel 22, a plurality of probe holders 25 each of which holds the foregoing ultrasonic probe are provided. On the right side of the foregoing operation panel 22, a gel holder 26 which holds a gel vessel is provided.

In a part of the foregoing operation panel 22, a rise portion 22a which upwardly rises is formed. The rise portion 22a is formed above the foregoing arm 13. The lower surface side of the foregoing rise portion 22a is formed as an inclined surface 22b. The inclined surface 22b is formed to prevent interference between the arm 13 and the foregoing operation panel 22 when the foregoing arm 13 is downwardly rotated.

To the foregoing operation panel 22, the display unit 27 which displays an ultrasonic image is attached via the display unit support arm 28. The foregoing display unit 27 is an LCD display, and is an exemplary image display unit. On the other hand, the foregoing display unit support arm 28 is an exemplary support arm.

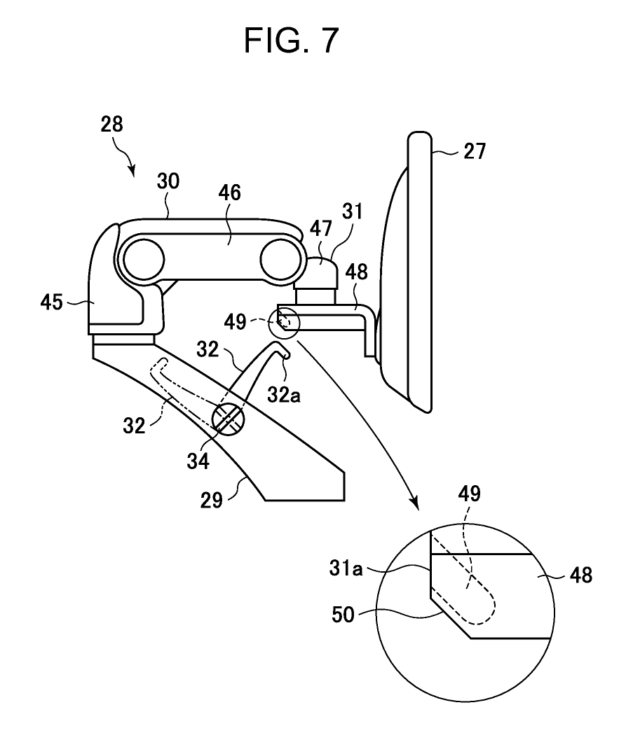

A description will be given of the foregoing display unit support arm 28 particularly with reference to FIGS. 7 to 12. Note that, in FIGS. 7 to 12, the depiction of the foregoing device main body 1A is omitted. The foregoing display unit support arm 28 is attached to the upper surface side of the foregoing operation panel 22, and includes a first arm portion 29, a second arm portion 30, and a third arm portion 31. The foregoing first arm portion 29 has one end portion thereof provided on the rise portion 22a of the foregoing operation panel 22 to be horizontally rotatable. Also, the foregoing first arm portion 29 is formed to upwardly extend from the foregoing operation panel 22 into an upwardly arcuate configuration. Accordingly, even in a state where the foregoing arm 13 is at the lowermost position Z, the foregoing arm attachment member 12 and the foregoing arm 13 are prevented from interfering with the foregoing first arm portion 29 (see FIG. 14).

The foregoing first arm portion 29 is provided with a rod-like engagement member 32 protruding from the surface thereof opposing the foregoing second and third arm portions 30 and 31. The engagement member 32 has a hooked portion 32a in the tip portion thereof. The hooked portion 32a is adapted to be engaged with an engagement hole 49, which will be described later.

As shown in FIG. 9, the foregoing engagement member 32 is provided in a storage hole 33 formed in the foregoing first arm portion 29. As shown in FIG. 9, in the storage hole 33, an opening 33a is formed in the longitudinal direction of the foregoing first arm portion 29. The foregoing engagement member 32 is provided rotatably in the foregoing storage hole 33 to be able to come in and go out of the foregoing opening 33a. Note that, in FIG. 9, the depiction of the foregoing engagement member 32 is omitted.

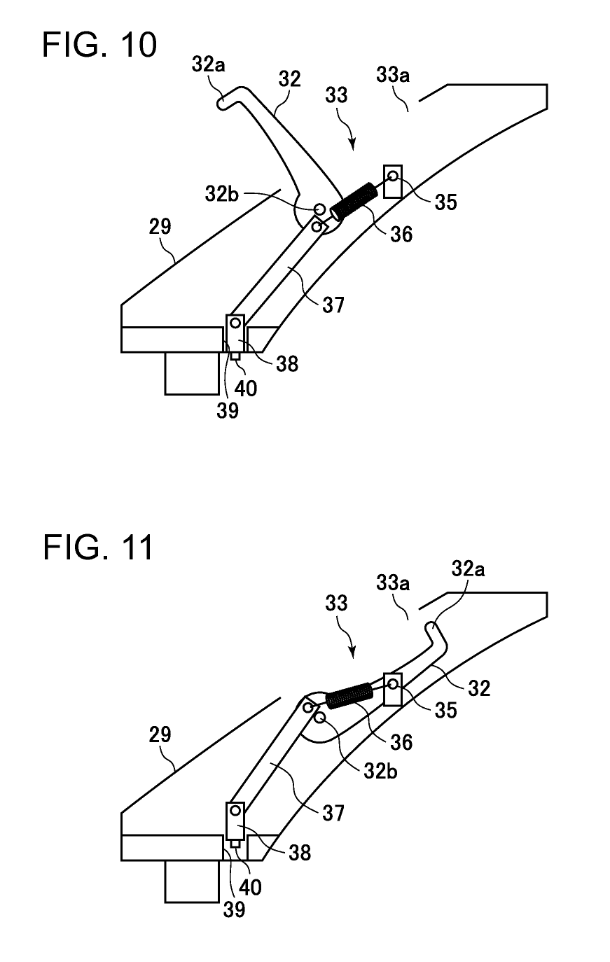

On a side surface of the foregoing first arm 29, a rotation knob 34 is provided. By rotating the rotation knob 34, the foregoing engagement 32 is rotated around a back-end-side rotation shaft 32b (see FIGS. 10 and 11). The foregoing engagement member 32 is adapted to rotate between an engagement position (FIG. 10) where the foregoing hooked portion 32a is engaged with the foregoing engagement hole 49 and a storage position (FIG. 11) where the foregoing hooked portion 32a is stored in the foregoing storage hole 33.

Between the back end side of the foregoing engagement member 32 and a spring fixing portion 35 provided in the foregoing storage hole 33, a spring 36 is provided. The spring 36 is a tension spring. As shown in FIG. 10, in a state where the foregoing engagement member 32 is at the engagement position, the engagement member 32 is biased by the foregoing spring 36 toward one end (the rise portion 22a of the foregoing device main body 1A) side of the foregoing first arm portion 29 to retain the engagement position.

Also, as shown in FIG. 11, in a state where the foregoing engagement member 32 is at the storage position, the engagement member 32 is biased by the foregoing spring 36 toward the other end (toward the foregoing second arm portion 30) side of the foregoing first arm portion 29 to retain the storage position.

To the foregoing engagement member 32, a plunger 38 is connected via a link 37. The plunger 38 is provided in the foregoing first arm portion 29 into a state where it is capable of advancing and retracting in a plunger hole 39 opened in the surface opposing the foregoing rise portion 22a on one end side of the foregoing first arm portion 29.

In the foregoing plunger 38, a rod 40 is provided. The rod 40 is adapted to project from the tip portion of the foregoing plunger 38 under the resilient force of an embedded spring (not shown) provided in the foregoing plunger 38.

In the state where the foregoing engagement member 32 is at the engagement position, the foregoing plunger 38 is adapted to advance to a position where the foregoing rod 40 projects from the foregoing plunger hole 39. On the other hand, in the state where the engagement member 32 is at the storage position, the foregoing plunger 38 is adapted to retract to a position where the foregoing rod 40 retracts into the foregoing plunger hole 39.

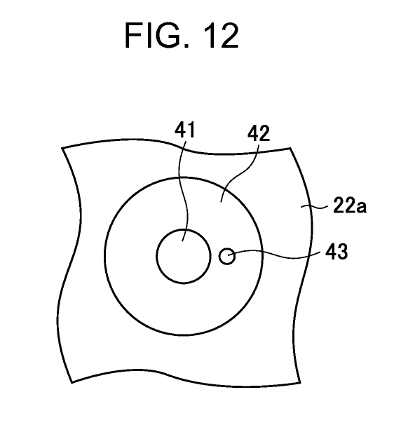

Here, as shown in FIG. 12, in the upper surface of the foregoing rise portion 22a, a support hole 41 into which one end portion of the foregoing first arm portion 29 is rotatably inserted to be supported thereby is provided. In FIG. 12, a numeral 42 shows a mounting surface of the upper surface of the foregoing rise portion 22a on which one end portion of foregoing first arm portion 29 is mounted. In the mounting surface 42, a rod projection hole 43 is provided in the vicinity of the foregoing support hole 41. The rod projection hole 43 is provided at a position with which the position of the foregoing rod 40 coincides in a state where the foregoing first arm portion 29 is directed to face the foregoing front surface side F and the foregoing back surface side B (the state of FIGS. 1 to 4) and at which the rod 40 can project.

When the foregoing engagement member 32 is at the engagement position and the foregoing rod 40 is not positioned over the foregoing rod projection hole 43, the foregoing rod 40 is pressed by the foregoing mounting surface 42 to be retracted into the foregoing plunger 38. In this state, the foregoing first arm portion 29 is in a horizontally rotatable state. On the other hand, when the foregoing engagement member 32 is at the engagement position and the foregoing rod 40 is at the position of the foregoing rod projection hole 43, the foregoing rod 40 projects into the foregoing rod projection hole 43 under the resilient force of the foregoing embedded spring. This inhibits the horizontal rotation of the foregoing first arm portion 29.

On the other end portion of the foregoing first arm portion 29, one end portion of the foregoing second arm portion 30 is provided. The second arm portion 30 has a horizontal rotation member 45 formed to upwardly extend from the foregoing first arm portion 29 and a vertical rotation member 46. The foregoing horizontal rotation member 45 is provided on the foregoing first arm portion 29 to be horizontally rotatable. The foregoing vertical rotation member 46 is provided on the foregoing horizontal rotation member 45 to be vertically rotatable. Therefore, the foregoing second arm portion 30 is horizontally and vertically rotatable with respect to the foregoing first arm portion 29.

In the foregoing vertical rotation member 46, a parallel link mechanism is provided, though not shown. The parallel link mechanism has a spring and, by the action of the spring, the foregoing vertical rotation member 46 is brought to rest at a desired position within the range of rotation.

On the other end portion of the foregoing second arm portion 30, the foregoing third arm portion 31 is provided. The third arm portion 31 has a cylindrical member 47 and an L-shaped member 48. The foregoing cylindrical member 47 is provided vertically rotatable with respect to the foregoing vertical rotation member 46. The foregoing L-shaped member 48 is provided on the foregoing cylindrical member 47 to be horizontally rotatable.

The end portion of the foregoing cylindrical member 47 opposite to that closer to the foregoing second arm portion 30 is located below the second arm portion 30, i.e., closer to the foregoing first arm portion 29 and, on the end portion, the foregoing L-shaped member 48 is provided to be perpendicular thereto. Thus, the foregoing L-shaped member 48 forms a stepped portion located closer to the foregoing engagement member 32 than the foregoing second arm portion 30.

The foregoing L-shaped member 48 has one end side provided with an engagement hole 49 and the other end side provided with the foregoing display unit 27. The display unit 27 may also be provided on the foregoing L-shaped member to be vertically rotatable.

The foregoing engagement hole 49 is opened at a position which is brought into opposing relation to the foregoing engagement member 32 by the vertical rotation of the foregoing second arm portion 30 and at which the engagement member 32 can be engaged with the engagement hole 49. In the present example, the foregoing engagement hole 49 is opened in a one-end-side end surface 31a of the foregoing third arm portion 31. The end surface 31a is an exemplary opposing surface.

The foregoing engagement hole 49 is provided at an angle which allows the foregoing hooked portion 32a to be engaged with the engagement hole 49 when a one-end-side portion of the foregoing L-shaped member 48 is in a horizontal state. In a state where the foregoing first arm portion 29 and the foregoing second and third arm portions 30 and 31 oppose each other and the individual arm portions 29 to 31 are in a linearly aligned state when viewed in plan view, the foregoing hooked portion 32a is adapted to be engaged with the foregoing engagement hole 49.

On one end side of the foregoing L-shaped member 48, a guide surface 50 is provided below the foregoing engagement hole 49. When the foregoing second arm portion 30 is downwardly rotated so as to downwardly move the foregoing L-shaped member 48 located above the foregoing engagement member 32, the foregoing hooked portion 32a comes in contact with the foregoing guide surface 50 to slide over the guide surface 50 and be guided into the foregoing engagement hole 49.

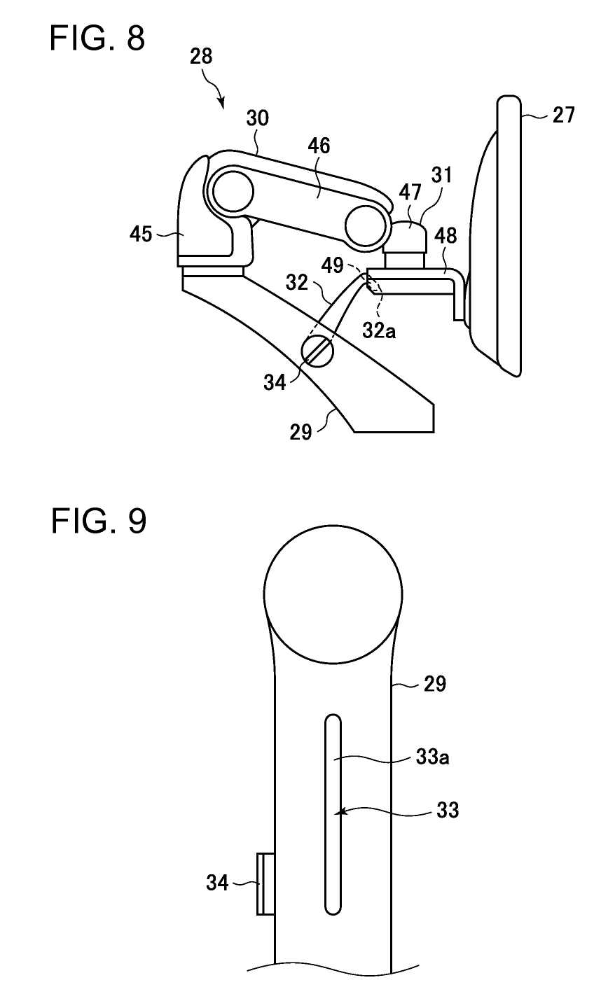

A description will be given of the function of the ultrasonic image display device 1 in the present example. When the ultrasonic image display device 1 is moved, the foregoing display unit support arm 28 is locked to fix the position of the foregoing display unit 27. The following is a specific description thereof. The foregoing first arm portion 29 and the foregoing second and third arm portions 30 and 31 are positioned into an opposing and linearly aligned state when viewed in plan view (see FIG. 8) to bring the foregoing hooked portion 32a into engagement with the foregoing engagement hole 49 (see FIG. 8). By thus merely bringing the foregoing hooked portion 32a into engagement with the foregoing engagement hole 49, the horizontal and vertical rotation of the foregoing second arm portion 39 is inhibited, and the horizontal and vertical rotation of the foregoing third arm portion 31 is also inhibited.

In a state where the foregoing engagement member 32 is at the engagement position and protrudes from the foregoing storage hole 33, when the foregoing first arm portion 29 is horizontally rotated into a state where it is directed to face either of the foregoing front surface side F and the foregoing back surface side B, the rod 40 of the foregoing plunger 38 projects into the foregoing rod projection hole 43 to inhibit the horizontal rotation of the foregoing first arm portion 29. Thus, the foregoing display unit support arm 28 is locked to allow the foregoing display unit 27 to be fixed at a position where a display surface 27a thereof faces the foregoing front surface 6.

In accordance with the ultrasonic image display device 1 in the present example, with the rotation of the foregoing arm 13, the height positions of the foregoing operation panel 22 and the foregoing display unit 27 change. The operator sets, according to his or her posture at the time of ultrasonic scanning, the height positions of the foregoing operation panel 22 and the foregoing display unit 27.

The following is a specific description thereof The foregoing operation panel 22 and the foregoing display unit 27 are positioned at height positions corresponding not only to a state where the operator is standing or sitting on a chair but also to the case where the operator operates the foregoing operation panel 22 or performs ultrasonic scanning in a squatting posture. Specifically, when the operator is in a standing posture, the foregoing arm 13 is rotated to the foregoing uppermost position Y as shown in FIG. 13 to provide a state where the height positions of the foregoing operation panel 22 and the foregoing display unit 27 are highest. Alternatively, when the operator is in a posture of sitting on a chair, the foregoing arm 13 is positioned at the foregoing horizontal position X, as shown in FIGS. 1 to 4. Otherwise, when the operator is in a squatting posture, as shown in FIG. 14, the foregoing arm 13 is rotated to the foregoing lowermost position Z to provide a state where the heights of the foregoing operation panel 22 and the foregoing display unit 27 are lowest.

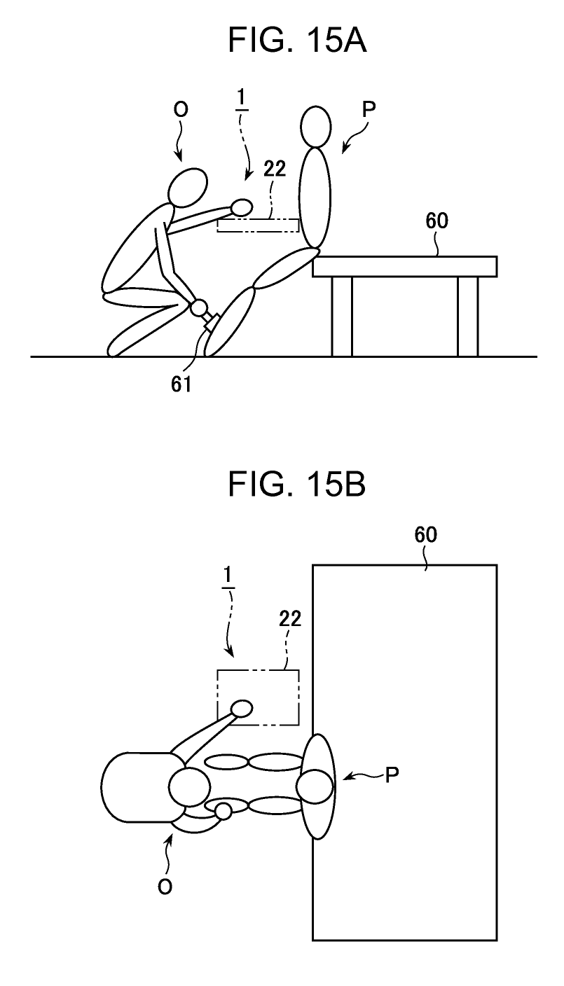

Here, referring to FIGS. 15A and 15B, a description will be given of an example of a use situation of the foregoing ultrasonic image display device 1 when the foregoing arm 13 is rotated to the foregoing lowermost position Z. In FIGS. 15A and 15B, 60 denotes a bed, and a subject under examination P is sitting on the bed 60 with his or her legs sticking out. In the case of scanning an ankle or the like of the subject under examination P in such a posture using an ultrasonic probe 61 (shown only in FIG. 15A), an operator O performs scanning in a squatting posture, while facing the subject under examination P. The foregoing ultrasonic image display device 1 is placed on the left side of the operator O facing the subject under examination P (in FIGS. 15A and 15B, only the foregoing operation panel 22 is shown by the imaginary line). However, the body position of the operator O and the position and orientation of the foregoing ultrasonic image display device 1 that are shown in FIGS. 15A and 15B are exemplary, and not limited to those shown in the drawing.

By positioning the foregoing arm 13 at the foregoing lowermost position Z, the height position of the foregoing operation panel 22 becomes about 65 cm. Therefore, if the operator positions the foregoing arm 13 at the foregoing lowermost position Z in a squatting posture, the operator can operate the foregoing operation panel 27 without assuming a difficult body position to achieve. In addition, the display unit 27 is also at the lowest height position where the display unit 27 is easier to view.

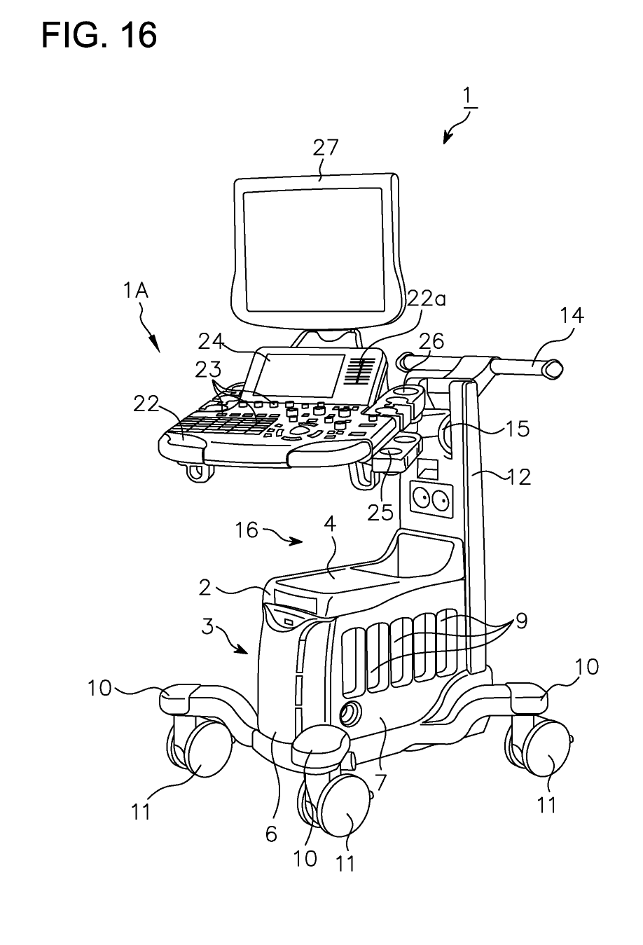

The operator may also horizontally rotate the foregoing operation panel 22 so as to orient the foregoing operation panel 22 in a direction which assures the operator of easier operation as shown in, for example, FIG. 16.

As described above, the foregoing arm 13 is attached to the attachment portion 15 of the arm attachment member 12 provided on the foregoing back surface side B. The attachment portion 15 is provided above the foregoing casing unit 2, and the foregoing arm 13 is provided above the foregoing casing unit 2 so as to extend in the device front-rear direction and vertically rotate above the casing unit 2. Therefore, it is possible to reduce the depth (length in the device front-rear direction) of the foregoing ultrasonic image display device 1. In addition, since the foregoing arm 13 rotates upwardly and downwardly above and below the foregoing horizontal position X, the difference in the position of the foregoing operation panel 22 in the device front-rear direction due to the rotation of the foregoing arm 13 is reduced. As a result, the depth of the foregoing ultrasonic image display device 1 is reduced to allow space-saving installation.

In the foregoing ultrasonic image display device 1, the foregoing plurality of connectors 9 are provided in the right side surface of the foregoing casing unit 2, and therefore the width of the casing unit 2 can be reduced. In addition, since the foregoing caster attachment members 10 are provided to protrude laterally from the foregoing casing unit 2, even when the width of the foregoing casing unit 2 is reduced, the stability of the foregoing ultrasonic image display device 1 can be ensured. For example, if the foregoing ultrasonic image display device 1 is installed such that the foregoing caster attachment members 10 are inserted under the foregoing bed 60, the ultrasonic image display device 1 can be brought closer to a bedside. Therefore, it is possible to improve the operability of the foregoing operation panel 22 and the visibility of the foregoing display unit 27 for the operator. In addition, even when a bedside space is narrow, the ultrasonic image display device 1 can be installed.

While the present invention has thus been described heretofore using the foregoing exemplary embodiment, the present invention is not limited thereto. It will be appreciated that various changes and modifications can be made within the spirit and scope of the present invention. For example, in the foregoing embodiment, each of the angle of upward rotation of the foregoing arm 13 from the foregoing horizontal position X and the angle of downward rotation thereof from the foregoing horizontal position X is θ° and the same, but the angle of upward rotation from the foregoing horizontal position X and the angle of downward rotation from the foregoing horizontal position X may also be different.

1. A support arm configured to support an image display unit on a device main body of an image display device, said support arm comprising:
a first arm portion comprising a first end portion coupled to the device main body;
a second arm portion comprising a first end portion coupled to a second end portion of said first arm portion, and vertically rotatable with respect to said first arm portion; and
a third arm portion comprising a first end portion coupled to a second end portion of said second arm portion, and comprising a second end portion coupled to the image display unit, wherein
said first arm portion comprises a rod-like engagement member comprising a hooked portion in a tip portion thereof, and said first end portion of said third arm portion comprises an engagement hole configured to engage said hooked portion.

2. A support arm according to claim 1, wherein said engagement hole is positioned such that said hooked portion can be brought into engagement with said engagement hole by vertical rotation of said third arm portion in association with said second arm portion.

3. A support arm according to claim 1, wherein, with said first arm portion opposing said second and third arm portions, said hooked portion engages said engagement hole.

4. A support arm according to claim 3, wherein
said engagement member protrudes from a surface of said first arm portion opposing said second and third arm portions, and
said engagement hole is positioned such that said engagement hole is brought into opposing relation to [[the]] said engagement member by the vertical rotation of said second arm portion and such that the engagement member is configured to engage the engagement hole.

5. A support arm according to claim 4, wherein said third arm portion further comprises a stepped portion located closer to said engagement member than said second arm portion, said stepped portion comprising an opposing surface that opposes said engagement member when said engagement member engages said engagement hole, and said engagement hole is defined in said opposing surface.

6. A support arm according to claim 3, wherein, when said first, second, and third arms are linearly aligned when viewed in plan view, said hooked portion engages said engagement hole.

7. A support arm according to claim 1, wherein said third arm portion comprises a guide surface configured to contact said hooked portion by the vertical rotation of said second arm portion to guide said hooked portion into said engagement hole.

8. A support arm according to claim 1, wherein
said first arm portion comprises a storage hole configured to store said engagement member therein, and
said engagement member is configured to protrude from said storage hole such that said hooked portion engages said engagement hole.

9. A support arm according to claim 1, wherein said second arm portion is coupled to said second end portion of said first arm portion such that said second arm portion is horizontally rotatable with respect to said first arm portion.

10. A support arm according to claim 1, wherein said third arm portion is coupled to said second end portion of said second arm portion such that said third arm portion is vertically rotatable with respect to said second arm portion.

11. A support arm according to claim 1, wherein said first arm portion is coupled to the device main body such that said first arm portion is horizontally rotatable with respect to the device main body.

12. An image display device comprising:
a device main body;
an image display device; and
a support arm supporting said image display unit on said device main body., said support arm comprising:
a first arm portion comprising a first end portion coupled to said device main body;
a second arm portion comprising a first end portion coupled to a second end portion of said first arm portion, and vertically rotatable with respect to said first arm portion; and
a third arm portion comprising a first end portion coupled to a second end portion of said second arm portion, and comprising a second end portion coupled to said image display unit, wherein
said first arm portion comprises a rod-like engagement member comprising a hooked portion in a tip portion thereof, and said first end portion of said third arm portion-comprises an engagement hole configured to engage said hooked portion.

13. An image display device according to claim 12, wherein said device main body comprises:
a casing unit;
an arm attached to an attachment portion positioned above the casing unit such that said arm is vertically rotatable and extends in a front-rear direction of said image display device, said arm positioned above said casing unit; and
an operation panel coupled to a front end side of said arm, wherein
said attachment portion is positioned a predetermined height from an upper surface of said casing unit such that said arm is rotatable upwardly and downwardly above and below a horizontal position of said arm.

14. An image display device according to claim 13, wherein said attachment portion is coupled in an arm attachment member protruding upwardly above said upper surface of said casing unit.

15. An image display device according to claim 14, wherein said arm attachment member is located on a back surface side of said image display device, and said arm extends from said back surface side toward a front surface side.

16. An image display device according to claim 13, wherein a height of said attachment portion from said upper surface of said casing unit is set such that a space portion that ensures the rotation of said arm is formed above said casing unit.

17. An image display device according to claim 13, wherein an angle of upward rotation of said arm from the horizontal position to an uppermost position is the same as an angle of downward rotation of said arm from the horizontal position to a lowermost position.

18. An image display device according to claim 13, wherein an angle of upward rotation of said arm from the horizontal position to an uppermost position is different from an angle of downward rotation of said arm from the horizontal position to a lowermost position.

19. An image display device according to claim 13, wherein a caster which supports said image display device at an installation surface is attached to a caster attachment member protruding laterally from said casing unit.

20. An image display device according to claim 19, wherein a height of an attachment surface of said caster in said caster attachment member is higher than a lower surface of said casing unit.
